(19) United States
(12) Patent Application Publication
(10) Pub. No.: US 2005/0194640 A1
(43) Pub. Date: Sep. 8, 2005

(54) Organic thin-film transistor

(76) Inventor: Pavel I. Lazarev, London (GB)

Correspondence Address: Aldo J. Test;DORSEY & WHITNEY LLP, Suite 3400, 4 Embarcadero Center, San Francisco, CA, 94111, US

(21) Appl. No.: 10/968,404

(22) Filed: Oct. 18, 2004

Related U.S. Application Data
(60) Provisional application No. 60/512,241, filed on Oct. 17, 2003.

(51) Int. Cl. H01L 29/08

(52) U.S. Cl. 257/347; 257/40

(57) ABSTRACT

The present invention relates to organic thin-film transistors using an organic compound in the semiconductor layer thereof. The organic semiconductor layer is made by means of Cascade Crystallization Process. Said layer is characterized by a globally ordered crystalline structure with intermolecular spacing of 3.4±0.3 Å in the direction of one crystal axis. This layer is formed by rodlike supramolecules comprising at least one polycyclic organic compound with conjugated π-system and has electron-hole type of conductivity.

### CROSS REFERENCE TO RELATED APPLICATIONS

This application claims the priority of the U.S. Provisional Patent Application Ser. No. 60/512,241, filed Oct. 17, 2003, the disclosure of which is hereby incorporated by reference in its entirety.

### FIELD OF THE INVENTION

The present invention relates to a thin-film transistor, and particularly to a thin-film-transistor using an organic compound as the semiconductor layer (hereinafter, referred to as OTFT).

### BACKGROUND OF THE INVENTION

A typical thin-film transistor, hereinafter referred to as TFT, consists of a number of layers and they can be configured in various ways. For example, a TFT may comprise a substrate, an insulator layer, a semiconductor layer, source and drain electrodes connected to the semiconductor layer, and a gate electrode adjacent to the insulator layer. When a potential is applied to the gate electrode, charge carriers are accumulated in the semiconductor at its interface with the insulator. As a result, a conducting channel is formed between the source and the drain, in which a current flows when a potential is applied to the drain. In conventional TFTs, inorganic semiconductors such as Si or GaAs have been used as the channel materials.

At present, TFTs find use in a number of applications such as the active drive matrices for large area displays. However, TFTs employing inorganic materials are often difficult and expensive to manufacture because of high-temperature processing and high vacuum conditions required for obtaining uniform devices over large areas. The number of TFTs which can be fabricated in a single process is limited by the size of wafers of such inorganic materials). As for the production of TFTs of this type, a method for manufacturing TFT on a glass substrate by using amorphous silicon or polycrystalline silicon (polysilicon) films as semiconductor layers is known. Amorphous silicon films can be obtained using a plasma chemical vapor deposition (CVD) process, and polysilicon films are usually obtained using a CVD process at low pressures. However, using the plasma CVD process, it is difficult to obtain TFTs of sufficient uniformity over a large area because of restrictions related to the production equipment and the difficulty of plasma control. Further, the system must be evacuated to a high vacuum before film deposition, which decreases throughput. According to the low-pressure CVD process, a film is produced by decomposing the initial gas at a relatively high temperature of 450-600° C. and, therefore, expensive glass substrates of high heat resistance must be used which is economically disadvantageous.

In the past decade, there has been a growing interest in developing TFTs which use organic materials. Organic devices offer the advantage of structural flexibility, potentially much lower manufacturing costs, and the possibility of conducting low-temperature processes on large areas. To gain full advantage of organic devices, it is necessary to develop materials and processes based on effective coating methods to form various elements of an organic thin-film transistor, hereinafter referred to as OTFT. In order to achieve large currents and fast switching, the semiconductor should possess high carrier mobility. For this reason, significant effort has been concentrated on the development of organic semiconductor materials with high mobility. The review of the progress in the development of such organic semiconductor materials is for example presented in the IBM Journal of Research & Development, 45, 1 (2001).

A variety of organic materials have been designed, synthesized and characterized as p-type semiconductors (in which the majority carriers are holes). Organic thin film transistor (OTFT) devices have been made using such materials. Among these, thiophene oligomers have been proposed as semiconducting materials in Garnier et al., Structural Basis for High Carrier Mobility in Conjugated Oligomers, Synth. Met., 45, 163 (1991). Benzodithiophene dimers are proposed as organic semiconductor materials in J. Liquindanum et al., Benzodithiophene Rings as Semiconducting Building Blocks”, Adv. Mater., 9, 36 (1997). Pentacene, which is a representative of polyacenes, is one of the most widely studied organic semiconductors and is proposed as a semiconducting material for OTFT devices in Dimitrakopoulos et al., Molecular Beam Deposited Thin Film of Pentacene for Organic Field-Effect Transistor Applications, J. Appl. Phys., 80, 2501-2508 (1996); Jackson et al., Pentacene Organic Thin-Film Transistors for Circuit and Display Applications, IEEE Trans. Electron Devices, 46, 1259-1263 (1999).

A number of organic π-conjugated materials have been used as the active layers in OTFTs (Current Opinion in Solid State & Materials Science, 2, 455-461 (1997); Chem. Phys., 227, 253-262 (1998). However, none of these materials have been found completely satisfactory for practical applications because they exhibit poor electrical performance, are difficult to process in large scale manufacture, or are not sufficiently robust to attack by atmospheric oxygen and water, which results in short working life of the related devices. For example, pentacene has been reported to give very high field effect mobilities but only when deposited under high vacuum conditions, see for example Synth. Metals, 41-43, 1127 (1991). A soluble precursor route has also been reported for pentacene which allows liquid processing, but this material requires subsequent heating at relatively high temperatures (140-180° C.) in vacuum to form the active layer, see for example Synth. Metals, 88, 37-55 (1997). The final performance of an OTFT formed using this process is very sensitive to the substrate and the conversion conditions, and has very limited usefulness in terms of a practical manufacturing process. Conjugated oligomers such as α-hexathiophene [Synth. Metals, 54, 435 (1993); Science, 265,1684 (1994)] were also reported to possess high OTFT mobility, but only when deposited under high vacuum conditions. Some semiconducting polymers such as poly(3-hexylthiophene) [Appl. Phys. Lett., 53, 195(1988)] can be deposited from solution but the deposits have been found unsatisfactory for practical applications. Borsenberger et al. [Jpn. J. Appl. Phys., Pt 2A, 34(12), L1597-L1598 (1995)] describe high mobility doped polymers comprising a bis(di-tolylaminophenyl)cyclohexane doped into a series of thermoplastic polymers, apparently of possible use as transport layers in xerographic photoreceptors. However, this paper does not suggest the usefulness of such materials in OTFTs.

An OTFT using a metal phthalocyanine is also known, see for example Chem. Phys. Lett., 142, 103 (1987). However, a metal phthalocyanine must be produced by a vacuum vapor deposition process, and therefore this type of OTFT encounters the same problems as in the case of using amorphous silicon as semiconductor layer when a large number of OTFT must be produced simultaneously and homogeneously.

As above, when a π-conjugated polymer obtained by electrochemical synthesis or an organic compound obtained by vacuum vapor deposition process are used in the semiconductor layer of an OTFT, it is difficult to produce OTFT on a substrate of large area simultaneously and homogeneously, which is disadvantageous from the practical point of view. Further, even when no gate voltage is applied or even when the OTFT is in an off state, a relatively large current flows between source electrode and drain electrode and, as a result, the drain current on-off ratio (or the element switching ratio) is small so as to make use of the OTFT as a switching element problematic.

An OTFT is known on the basis of pentacene [Yen-Yi Lin, David J. Gundlach, et al., Pentacene-Based Organic Thin-Film Transistors, IEEE Trans. lectron Dev., 44(8), 1325-1331 (1997)]. A heavily-doped silicon wafer is used as a substrate, and a 400-nm-thick oxide layer is thermally grown for use as the gate dielectric. A 50-nm pentacene active layer is deposited by thermal evaporation at 7×10-5 Pa after material purification by vacuum gradient sublimation. The devices are completed by evaporating a 50-nm gold layer through a shadow mask to form source and drain contacts and a 100-nm aluminum layer onto the wafer rear side to contact the gate. The OTFT has a channel length and width of 20 and 220 μm, respectively. The OTFT has a high field effect mobility, equal to 0.62 cm2/(V s) in the saturation region at VDS=−80 V. The carrier transport in field-induced channel in organic semiconductor layer (pentacene, and perhaps in most similar organic semiconductor systems) is dominated by the difficulty of moving carriers from a molecule to the adjacent one because of disorder, defects, and chemical impurities that can form trapping states.

There are two main configurations of mutual arrangement of source and drain contacts with respect to a semiconducting layer. If the source and drain are formed on the surface of the semiconducting layer, the configuration is called top-contact. In the other case, the organic semiconducting layer is deposited above the source and drain contacts. This configuration is called bottom-contact. Both configurations possess some advantages and disadvantages. In the former (top-contact) case, the masking layer should be deposited on the organic semiconductor layer. The masking layer should contain open windows for applying electrodes to the source and drain. Then the masking layer should be removed. During all these operations the organic semiconductor layer is subjected to additional chemical actions. These actions may lead to degradation of the electrical properties of the semiconducting layer.

A process that allows the photolithographic patterning of the source and drain electrodes on the insulator before depositing a semiconductor layer is more preferable. In this case, a semiconducting layer is not exposed to chemical reagents necessary for carrying out photolithography. The performance of devices fabricated using such a process is similar to or better than that of top-contact devices. Nevertheless, such devices have disadvantages too. If the vacuum-deposited organic semiconductor films of pentacene are grown on the metal contacts of source and drain, the crystal grain size is smaller than that in the films grown on insulating layers. The grain size is especially dramatically refined on gold contacts. Thus, the crystal structure of pentacene at the electrode edge poses limitations on the performance of the bottom-contact OTFT. Right at the edge of the Au electrode, there is an area with very small crystals and hence a large number of grain boundaries. Grain boundaries contain many morphological defects, which in turn are linked to the creation of charge-carrier traps with energy levels lying in the bandgap. hese defects can be considered as responsible for the reduced performance of bottom-contact pentacene-based OTFTs.

Much effort has been directed toward producing oriented (or ordered) organic semiconductor layers in order to improve carrier mobility. Wittmann and Smith [Nature, 352, 414 (1991)] describe a method for orienting (ordering) organic materials on an oriented poly(tetrafluoroethylene) substrate (PTFE). The oriented PTFE was obtained by sliding a bar of solid PTFE over a hot substrate. This technique is applied to use an oriented PTFE film as a substrate for depositing organic semiconductors in the manufacture of field effect transistors. The organic semiconductor also becomes oriented, this results in higher carrier mobility. The PTFE layer is deposited according to the technique of Wittmann and Smith, that is, by sliding solid PTFE on the hot substrate. However, this technique is difficult to apply on large areas.

Another method for ordered thin crystal film (or layer) manufacturing is described [U.S. Pat. Nos. 5,739,296 and 6,049,428 and the following publications: P. Lazarev et al., X-ray Diffraction by Large Area Organic Crystalline Nano-Films, Mol. Mater., 14(4), 303-311 (2001), and Y. Bobrov, Spectral Properties of Thin Crystal Film Polarizers, Mol. Mater. 14(3), 191-203 (2001)], the disclosures of which are incorporated by reference in their entirety.

### SUMMARY OF THE INVENTION

The disclosed invention represents an organic thin film transistor. The organic thin film transistor comprises an organic semiconductor layer, and an insulator layer having at least a part of one surface in contact with at least a part of one surface of the organic semiconductor layers, an electrically conducting gate electrode located on the other surface of the insulator layer, and electrically conductive source and drain electrodes in contact with one surface of the organic semiconductor layer. The organic semiconductor layer is characterized by a globally ordered crystalline structure with intermolecular spacing of 3.4±0.3 Å in the direction of one crystal axis. The organic semiconductor layer is formed by rodlike supramolecules comprising at least one polycyclic organic compound with conjugated π-system, and possesses electron-hole type of conductivity.

### BRIEF DESCRIPTION OF THE DRAWINGS

A more complete assessment of the present invention and its numerous advantages will be readily understood by reference to the following detailed description, considered in connection with the accompanying drawings and detailed specification, all of which forms a part of the disclosure:

FIG. 1 shows the cross section of a first configuration of an OFET according to the present invention (top-contact configuration).

FIG. 2 shows the cross section of a second configuration of an OFET according to the present invention (bottom-contact configuration).

FIG. 3 shows the cross section of a third configuration of an OFET according to the present invention (bottom-contact configuration).

FIG. 4 shows the cross section of a fourth configuration of an OFET according to the present invention (top-contact configuration).

FIG. 5 shows the temperature dependence of resistance of an uncovered organic semiconductor.

FIG. 6 shows the Arrhenius plot of the resistance as a function of temperature of an uncovered organic semiconductor.

FIG. 7 shows an OTFT structure with top source and drain contacts.

FIG. 8 shows an OTFT structure with bottom source and drain contacts.

FIG. 9 shows the characteristics of one OTFT sample with organic semiconductor layers made by means of Cascade Crystallization Process.

FIG. 10 shows the characteristics of other OTFT samples with organic semiconductor layers made by means of Cascade Crystallization Process.

### DETAILED DESCRIPTION OF THE INVENTION

Having generally described the present invention, a further understanding can be obtained by reference to the specific preferred embodiments, which are provided herein for purposes of illustration only and are not intended to limit the scope of the appended claims.

In a preferred embodiment, the disclosed invention provides an organic thin film transistor which comprises an organic semiconductor layer and an insulator layer with at least a part of one surface in contact with at least a part of one surface of the semiconductor layer. An electrically conducting gate electrode located on other surface of the insulator layer, and electrically conductive source and drain electrodes are in contact with one surface of the organic semiconductor layer. In one variant of the disclosed invention, the organic thin film transistor further comprises a substrate which carries said organic semiconductor layer and insulator layer.

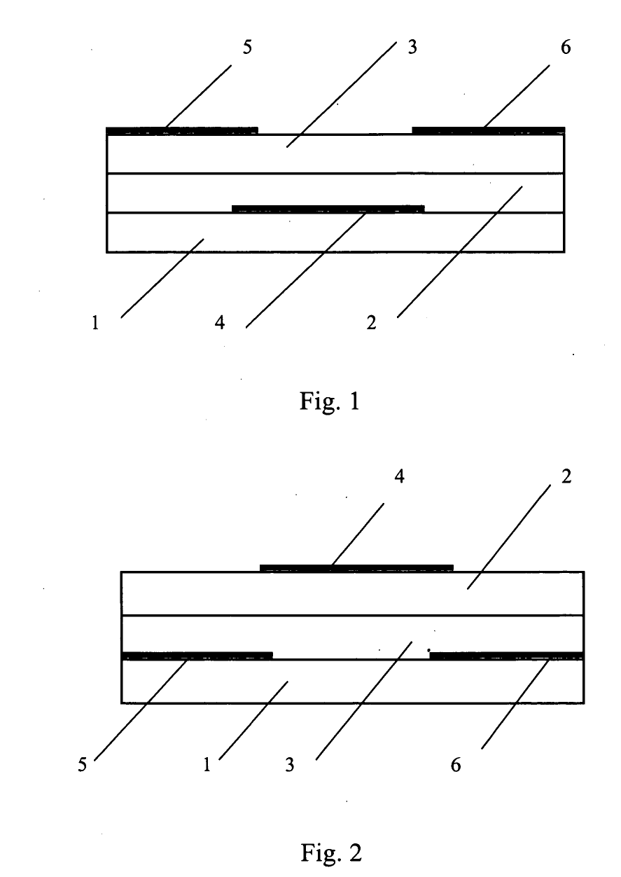

FIG. 1 schematically shows an organic thin film transistor, wherein an electrically conducting gate electrode 4 is located on the substrate 1; an insulator layer 2 is located on said electrically conducting gate electrodes; an organic semiconductor layer 3 is located on said insulator layer 2 substantially overlapping with said gate electrode; and electrically conducting electrode source 5 and drain electrode 6 is located on the top surface of said organic semiconductor layer.

FIG. 2 schematically shows an organic thin film transistor, wherein the electrically conductive source electrode 5 and drain electrode 6 are located on the substrate 1; an oganic semiconductor layer 3 is located on said source electrode, drain electrode and substrate; an insulator layer 2 is located top of on said organic semiconductor layer 2; and the electrically conducting gate electrode 4 is located on the top surface of said insulator layer overlying the regions between said source and drain electrodes.

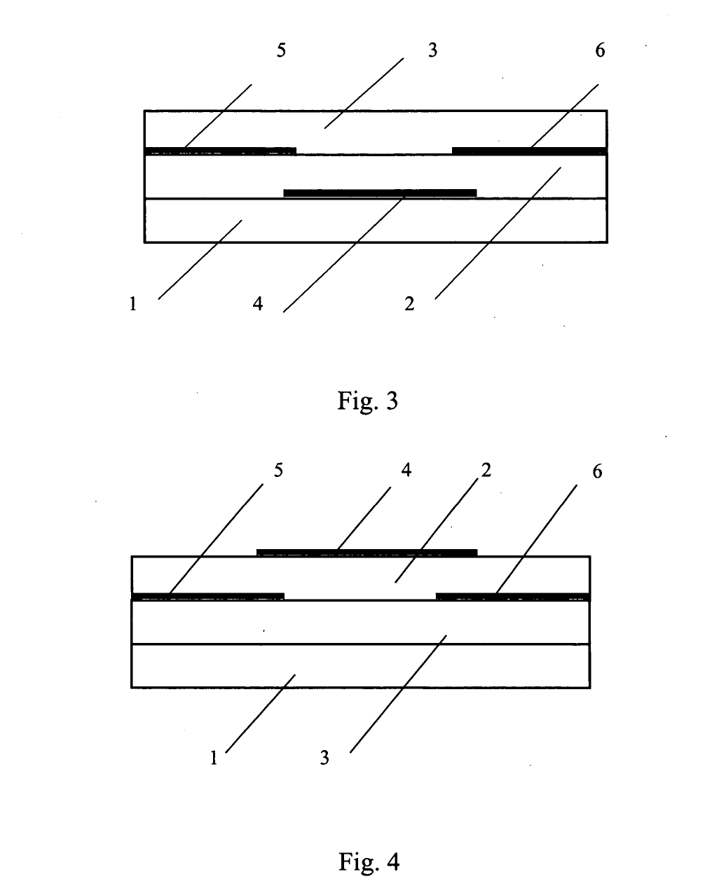

FIG. 3 schematically shows an organic thin film transistor, wherein the electrically conducting gate electrode 4 is located on the substrate 1; the insulator layer 2 is located on said electrically conducting gate electrode; the spaced electrically conductive source electrode 5 and drain electrode 6 are located on said insulator layer; and an organic semiconductor layer 3 is located on said source and drain electrodes with insulator layer 2 substantially overlapping with said gate and source electrodes.

FIG. 4 schematically shows an organic thin film transistor, wherein an organic semiconductor layer 3 is located on a substrate 1; spaced electrically conductive source electrode 5 and drain electrode 6 are located on said organic semiconductor layer; an insulator layer 2 is located on said source electrode, drain electrode and organic semiconductor layer; and an electrically conducting gate electrode 4 is located on said insulator layer.

The organic semiconductor layer is characterized by a globally ordered crystalline structure with intermolecular spacing of 3.4±0.3 Å in the direction of one crystal axis. This organic semiconductor layer is formed by rodlike supramolecules comprising at least one polycyclic organic compound with conjugated π-system, and possesses electron-hole type of conductivity. The organic semiconductor layer is made by means of Cascade Crystallization Process.

The Cascade Crystallization Process involves a chemical modification step and four steps of ordering during the organic semiconductor layer formation. The chemical modification step introduces hydrophilic groups (ionogenic groups) on the periphery of the molecule in order to impart amphiphilic properties to the molecule. Amphiphilic molecules stack together in supramolecules, which is first step of ordering. By choosing specific concentration, supramolecules are converted into a liquid-crystalline state to form a lyotropic liquid crystal, which is the second step of ordering. The lyotropic liquid crystal is deposited under the action of a shear force (or meniscus force) onto a substrate, so that the shear force (or the meniscus) direction determines the crystal axis direction in the resulting solid conjugated aromatic crystalline layer. This shear-force-assisted directional deposition is the third step of ordering. The last, fourth ordering step of the Cascade Crystallization Process is drying/crystallization, which converts the lyotropic liquid crystal into a solid conjugated aromatic crystalline layer.

The Cascade Crystallization Process is a simple and economically effective method. This method ensures a high degree of anisotropy and crystallinity of the layers, offers the possibility of obtaining thin conjugated aromatic crystalline layer of arbitrary shape (including multi-layer coatings on curvilinear surfaces), and is ecologically safe and low labor and energy consuming. The Cascade Crystallization Process is characterized by the following sequence of technological operations:
1) Chemical modification of the compound and formation of supramolecules (the first step of ordering);
2) Lyotropic liquid crystal formation (the second step of ordering);
3) Application of a lyotropic liquid crystal of at least one organic compound onto a substrate;
4) External liquefying action upon the lyotropic liquid crystal in order to decrease its viscosity;
5) External aligning action upon the lyotropic liquid crystal in order to impart a predominant orientation to particles of the colloid solution (the third step of ordering);
6) Termination of the external liquefying action and/or application of an additional external action so as to restore the lyotropic liquid crystal viscosity on at least the initial level;
7) Drying (the fourth step of ordering).

Below we present some stages of Cascade Crystallization Process in more detail.

The formation and structure of supramolecular aggregates in a lyotropic liquid crystal are determined by the concentration and geometry of molecules. In particular, the molecules may combine into lamellae, disk-like (disk-shaped) or rod-like (rod-shaped) micelles, or asymmetric aggregates. Lyotropic liquid crystals usually appear as ordered phases composed of rod-like surfactant molecules in water. These asymmetric (anisometric) aggregates form a nematic liquid crystal or a smectic columnar phase of either nonchiral or chiral (cholesteric phase) nature.

The external liquefying action upon the lyotropic liquid crystal, aimed at decreasing the viscosity, and the external aligning action upon the lyotropic liquid crystal, aimed at imparting a predominant orientation to the particles, can be performed simultaneously, or the external aligning action upon the lyotropic liquid crystal can be performed in the course of the external liquefying action.

The external liquefying action upon the lyotropic liquid crystal can be performed by local and/or total heating of the substrate from the side opposite to that on which the crystal film is formed, and/or by local and/or total heating of the substrate and/or the colloid solution layer from the side on which the conjugated aromatic crystalline layer is formed.

The external liquefying action upon said layer can be performed by a mechanical factor, for example, by shear, applied to the lyotropic liquid crystal layer on a substrate. Thixotropic properties of the lyotropic liquid crystal will be used in this case. The thixotropy implies the ability of a material to decrease viscosity under shear and to regain the initial viscosity after termination of shear. Highly thixotropic lyotropic liquid crystals are capable of regaining viscosity quickly after the termination of shear. Thus viscosity of thixotropic materials is a function of shear stress or shear rate. The viscosity of thixotropic materials diminishes when the shear stress (or shear rate) increases.

There are several methods for orienting liquid crystals. The process of orientation of thermotropic liquid crystals has been extensively studied from the standpoint of both basic problems and applications. As a rule, orientation technologies employ a special unidirectional treatment of plates (substrates) contacting with the liquid crystal material or confining the liquid crystal volume. The external alignment action can be achieved through interaction of a lyotropic liquid crystal with a specially prepared substrate possessing anisotropic properties or covered with special alignment layers. According to the known method, the aforementioned substrates are coated with a special polymer (e.g., polyimide) or with a surfactant layer in order to obtain the desired alignment effects. Rubbing this polymer layer renders it capable of producing the aligning action.

The direction of rubbing (i.e., the direction of desired orientation of a thermotropic liquid crystal), is imparted to molecules in the liquid crystal film by means of anisotropic molecular interactions between the alignment film and molecules in the liquid crystal layer adjacent to the substrate. Preferred direction in the liquid crystal is determined by the unit vector n called the liquid crystal director. The alignment action of an anisotropic (e.g., rubbed) substrate upon a liquid crystal is based on the phenomenon called “anchoring”. Anchoring is the standard means of orienting in the displays based on thermotropic liquid crystals. The corresponding alignment techniques are well known for thermotropic liquid crystals. However, these methods may be inapplicable to lyotropic liquid crystals because of significant differences between the two classes of these systems.

Lyotropic liquid crystals are much more difficult to orient by anchoring than thermotropic ones. This is related to the fact that most liquid crystals of the former type are based on amphiphilic substances (surfactants) soluble either in water or in oil. The amphiphilic molecules possess a polar (hydrophilic) head and a nonpolar (hydrophobic) aliphatic tail. When surfactant molecules are brought into contact with a substrate, the amphiphilic character results in the general case in their being oriented perpendicularly to the substrate surface. Both the polar hydrophilic head and the nonpolar hydrophobic tail are involved in the process of alignment, which results in the perpendicular orientation of molecules with respect to the substrate surface. This orientation, called homeotropic, is characterized by the preferred direction (perpendicular to the substrate surface), which also represents the crystal axis of the liquid crystal.

The external alignment action upon the surface of an applied colloid solution can be produced by directed mechanical motion of at least one alignment device representing a knife and/or a cylindrical wiper and/or a flat plate oriented parallel to the applied layer surface and/or at an angle to this surface, whereby a distance from the substrate surface to the edge of the aligning instrument is preset so as to obtain a crystal film of the required thickness. The surface of the alignment instrument can be provided with certain topography. The alignment process can be performed using heated instruments.

The external aligning action upon a lyotropic liquid crystal is provided by passing it through a spinneret under pressure in order to impart a predominant orientation to the colloid solution.

Restoration of said layer viscosity, at least on the initial level, can be achieved by terminating the liquefying action either in the course of or immediately after the alignment. After restoration of the lyotropic liquid crystal viscosity on the initial level, an additional aligning action upon the system can be produced in the same direction as that in the main alignment stage.

The drying stage should be performed at room temperature and a humidity of not less than 50%. After drying, conjugated aromatic crystalline layers usually retain about 10% of solvent. Prior to performing subsequent stages according to the disclosed method, the content of solvent in the layer should be decreased to 2-3% by additional annealing.

Upon accomplishing the above operations, Cascade Crystallization Process yields organic semiconductor layers with globally ordered crystalline structure, which is characterized by intermolecular spacing of 3.4±0.3 Å in the direction of one crystal axis.

The major advantage of Cascade Crystallization Process is a weak dependence of the film on the surface defects of substrate. This weak dependence is due to the viscous and elastic properties of the lyotropic liquid crystal. The elastic layer of a liquid crystal prevents development of the defect field and inhibits defect penetration into the bulk of the deposited layer. Elasticity of the lyotropic liquid crystal acts against reorientation of the molecules under the action of the defect field. Molecules of the deposited material are packed into lateral supramolecules with a limited freedom of diffusion or motion.

The organic semiconductor layer produced by this method has a global order or, in other words, such a layer has a globally ordered crystal structure. The global order means that the deposition process controls the direction of the crystallographic axis of the anisotropic crystalline layer over the entire layer surface or substrate surface. Thus, the organic semiconductor layer differs from a polycrystalline layer, in which the uniform crystal structure is formed inside a separate crystal grain. The area of such a crystal grain is much smaller than the area of the substrate surface. In addition, the organic semiconductor layer is characterized by a limited influence of the substrate surface on its crystal structure. The organic semiconductor layer can be formed on a part of the substrate surface or on the entire surface, depending in the requirements. In both cases, the organic semiconductor layer is characterized by a global order.

The organic semiconductor layer obtained by this method possesses the globally ordered structure of a special type. This layer is not crystalline or polycrystalline in the usual sense. The organic semiconductor layer has monoclinic symmetry. Flat molecules of an organic substance, for example, of an aromatic organic dye, are packed in a layered crystalline structure with a flat plane oriented perpendicular to the surface of the substrate and the coating direction

In one embodiment, the electrically conducting gate electrode is located on the substrate; the insulator layer is located on said electrically conducting gate electrode and is in contact with them; the organic semiconductor layer is located on said insulator layer substantially overlapping said gate electrode; and the electrically conducting source and drain electrodes are located on said organic semiconductor layer and are in contact with this layer.

In another embodiment, the electrically conducting source and drain electrodes are located on the substrate; the organic semiconductor layer is located on said source electrode, drain electrode and substrate and is in contact with them; the insulator layer is located on said organic semiconductor layer and is in contact with this layer; and the electrically conducting gate electrode is located on said organic semiconductor layer and is in contact with this layer. In a further embodiment the electrically conducting gate electrode is located on the substrate; the insulator layer is located on said electrically conducting gate electrode and is in contact with them; the electrically conducting source and drain electrodes are located on said insulator layer and are in contact with this layer; and the organic semiconductor layer is located on and in contact with said source electrode, drain electrode, and the insulator layer. In a further embodiment, the organic semiconductor layer is located on the substrate; the electrically conducting source and drain electrodes are located on said organic semiconductor layer and are in contact with this layer; the insulator layer is located on said source electrode, drain electrode and organic semiconductor layer and is in contact with them; and the electrically conducting gate electrode is located on said insulator layer and is in contact with them. In a possible variant of the disclosed organic thin film transistor, electrically conductive source and drain electrodes are aligned relative to said gate electrode. The variant of the embodiment of the invention is possible when the organic thin film transistor further comprises an insulating passivation layer located on top of said transistor that protects it from further processing exposures and from ambient factors. In one embodiment, the substrate is selected from the group comprising glass, plastic, quartz and undoped silicon. In another embodiment, said plastic substrate is selected from the group comprising polycarbonate, Mylar, and polyimide. In one embodiment, the organic semiconductor layer is made of an organic semiconductor of the n-type. In this case, the gate electrodes are made of a material with a high electron work function. The material of said gate electrodes is selected from the group comprising nickel, gold, platinum, lead, ITO, or combinations thereof. In one embodiment, the source and drain electrodes are made of a material with a low electron work function. This embodiment is possible when the material of said gate electrodes is selected from the group comprising chromium, titanium, copper, aluminum, molybdenum, tungsten, indium, silver, calcium, or combinations thereof. In another embodiment, the organic semiconductor layer is made from an organic semiconductor of the p-type. In this case the source and drain electrodes are made of a material with low electron work function. Such embodiment of the OTFT is possible, when the material of said source and drain electrodes is selected from the group comprising chromium, titanium, copper, aluminum, molybdenum, tungsten, indium, silver, calcium, or combinations thereof. Such variant of embodiment of the invention is possible, when the gate electrodes are made of a material with high electron work function of. In this case, the material of said gate electrodes is selected from the group comprising nickel, gold, platinum, lead, ITO, or combinations thereof. Such variant of embodiment of OTFT is possible, when said gate electrodes are in the range between 30 nm and 500 nm thick and are produced by a process selected from the group comprising evaporation, sputtering, chemical vapor deposition, electrodeposition, spin coating, and electroless plating. In a preferred embodiment, the present invention provides the organic thin film transistor, wherein material of said insulator layer is selected from the group comprising silicon dioxide, silicon oxide, barium strontium titanate, barium zirconate titanate, lead zirconate titanate, lead lanthanum titanate, barium titanate, strontium titanate, barium magnesium fluoride, tantalum pentoxide, titanium dioxide, and yttrium trioxide. In one embodiment, said insulator layer has a thickness in the range between 80 nm and 1000 nm. In another embodiment, said insulator layer is produced by a process selected from the group including of sputtering, chemical vapor deposition, sol gel coating, evaporation, and laser ablation deposition. In one possible variant of the organic thin film transistor, at least one electrically conducting gate electrode is the multilayer structure comprised of layers made of different conducting materials. In another variant of the organic thin film transistor, at least one electrically conducting source electrode is the multilayer structure comprised of layers made of different conducting materials. In still another variant of the organic thin film transistor, at least one electrically conducting drain electrode is the multilayer structure comprised of layers made of different conducting materials.

### EXAMPLES

A number of experiments were conducted according to the present invention. These experiments are intended for illustration purposes only, and are not intended to limit the scope of the present invention in any way.

### Example 1

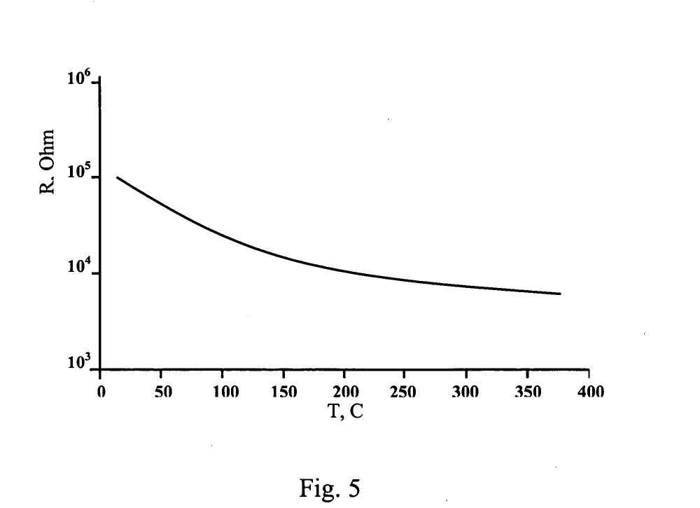

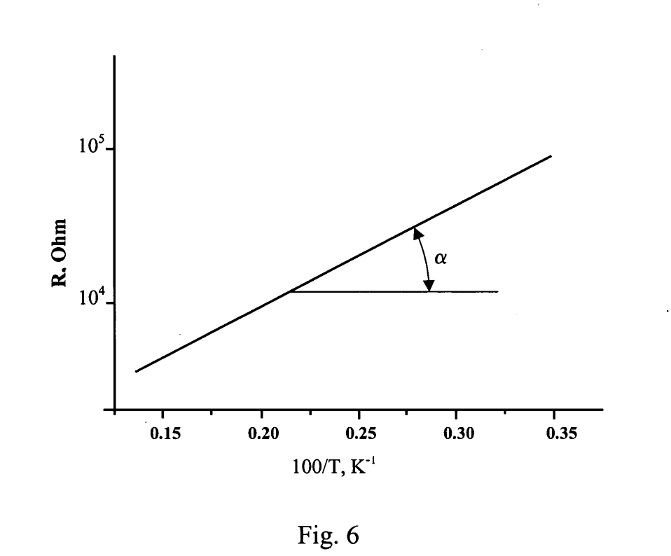

The resistance of the organic semiconductor layer was measured in situ during heating, and subsequent cooling down in vacuum. In some cases, the layer was exposed to atmospheric air at the end of the heating-cooling cycle. The experiments were carried out either with a SiO₂ protective layer or with an uncovered organic semiconductor layer. The results of experiments with uncovered sample of organic semiconductor layer are shown in FIGS. 5 and 6. The resistance was measured in a perpendicular direction relative to the direction of predominant orientation of particles of the colloid solution under external aligning action during of Cascade Crystallization Process.

In FIG. 5, the curve shows the temperature dependence of the resistance of a sample of organic semiconductor in the course of the heating-cooling cycles in vacuum. Here the temperature is increased from room temperature to 360° C. and then decreased to room temperature in vacuum. FIG. 5 shows that the resistance of the organic semiconductor layer is decreased when temperature is increased. Such temperature dependence of resistance is characteristic for a semiconducting material. This effect happens because in a semiconductor the number of the mobile charge carriers is increased with increasing temperature. The activation energy EA measured during the cooling is equal to 128 meV. The magnitude of the activation energy is evaluated according to the following formula: E_{A}=dln(R)/d(1/kT)=tg(α), where R—the resistance of the organic semiconductor layer, T—temperature of this layer in absolute degrees, k—Boltzmann constant, and α—angle of tilting shown in FIG. 6 of experimental dependence in respect to abscissa axis.

These characteristics are confirmed by the experiments with heating-cooling cycles of SiO₂-covered sample of organic semiconductor layer. The geometry of the experiment was the same. In these experiments, the samples were subjected to several heating-cooling cycles. The results are shown in FIG. 6. It is possible to note several important points. The protective SiO₂— layer did not allow the atmosphere to affect the sample surface. The value of the sample resistance upon heating up to a temperature of 380° C. is the same as that for the uncovered sample. This means that SiO₂-coating does not alter the electron properties of the sample. Both covered and uncovered samples show the same trends during heating: the resistance rises at virtually the same rate.

The value of resistance at 380° C. measured perpendicularly to the direction of predominant orientation is higher approximately by a factor of 3.5 than the resistance measured along the direction of predominant orientation. This anisotropy is much lower than that observed in the optical polarization experiments, where it was on the order of 10. This means most probably that the anisotropy may strongly depend on details of the sample preparation procedure.

### Example 2

The goal of the experiments cited below, the showing of capacity of organic semiconductor layers made by means of Cascade Crystallization Process to serve as active layers in an organic thin-film transistor.

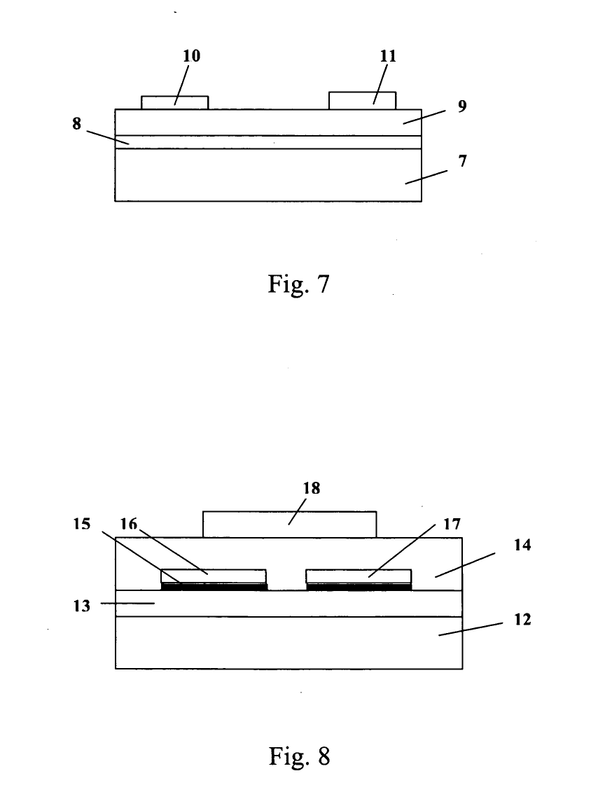

Two different techniques are used for making the organic thin-film transistor structure (OTFT) with organic semiconductor layer. In the first method the top contacts are used as a source and drain, and in the second method the bottom contacts are used. To obtain a transistor structure of the first type, the silicon wafer with a silicon dioxide insulator layer located on its top was used. This wafer was coated with organic semiconductor layer made by means of Cascade Crystallization Process, and then the contacts were formed on the wafer top as shown in FIG. 7. The OTFT structure with top source and drain contacts shown in FIG. 7 comprises a silicon wafer 7 that serves as a gate contact, an SiO₂ insulator layer 8, an organic semiconductor layer 9, and the gold source 10 and drain 11 contacts. The deposition procedure for the contacts consisted of several stages. The first step was cutting the Si/SiO₂ wafer covered by the organic semiconductor layer to the needed size. The second step was the placing of the mask. A mechanical mask was glued to the sample surface by means of Aquaricum silicone gel. Finally, the third step was the covering of the sample surface with gold using thermal evaporator NRC/Varian 3117 equipped with thickness monitor TM-350 by MAXTEC Inc. The processing pressure inside the evaporator is 10⁻⁶-10⁻⁷ Torr, evaporating current is 150 A, and the contact thickness was 50 nm. All steps were controlled visually using NIKON Eclipse L200 microscope. Two different mask sizes were used for deposition of the top contacts. The first provided 100 μm square contacts with a channel length of 10 μm. The second provided 250 μm square contacts with a channel length of 25 μm. To obtain a transistor structure of the second type, FIG. 8, the bottom contacts were made using a photolithography method. The device used to exposure the contacts was a Karl Suss MJB 3. To make the contacts a Temescal VES-2550 electron-beam evaporator with INFICTION IC/5 deposition controller was used. The SiO₂ layer was made using Airco Temescal CV-8 electron beam evaporator with an INFICTION XTC/2 deposition controller. The contacts were deposed perpendicular and parallel to the film coating direction. Different channel lengths and channel widths were available. The OTFT structure with bottom source and drain contacts is shown in FIG. 8. The aforesaid structure comprises the 500 μm Si wafer 12, which serves as a gate contact, a 200 nm thick SiO₂ insulator layer 13, an organic semiconductor layer 14 made by means of Cascade Crystallization Process, a 2.5 nm Titanium layer 15 for better adhesion of gold, a 5-50 nm thick golden source 16 and drain 17 contacts, and 6-800 nm thick SiO₂ protection layer 18. The obtained samples were measured, using Signatone S-1160 probe station and Keathley 4200 semiconductor characterization system.

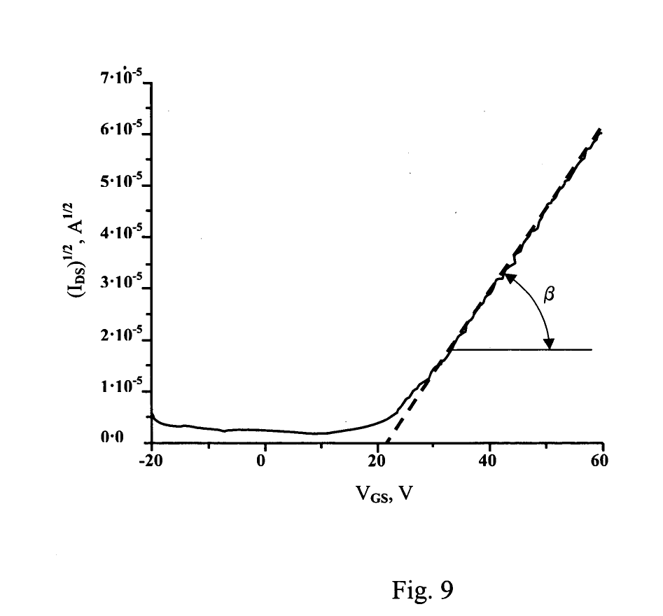

FIG. 9 illustrates the mobility characteristics of OFETs with organic semiconductor layer made by means of Cascade Crystallization Process. The linear regime of OTFT transistor was observed for low drain-source voltage (V_{DS}≈60V), followed by a saturation regime when the drain-source voltage (V_{DS}) exceeds the gate-source voltage (V_{GS}), when the saturation drain current (I_{DS}) is expressed by the following equation: I_{DS}=(W/2 L)μC₁(V_{GS}−V_{T}), where μ is the field-effect carrier mobility, W—the channel length (W—1000 μm), L—the channel length (L=10 μm), C_{I}—the capacitance per unit area of the insulator layer, VT—the threshold voltage, which one is determined by point of intersection of the broken line shown in the FIG. 9 with the abscissa axis. From the equation mentioned above follows, that the field-effect carrier mobility is expressed by the following equation: μ=2 L/(W·C_{I})·tg² (β), where β is the angle of tilting of the broken line with respect to abscissa axis as it is shown in FIG. 9. The mobility is approximately equal to 3×10⁻⁶ cm2/Vs.

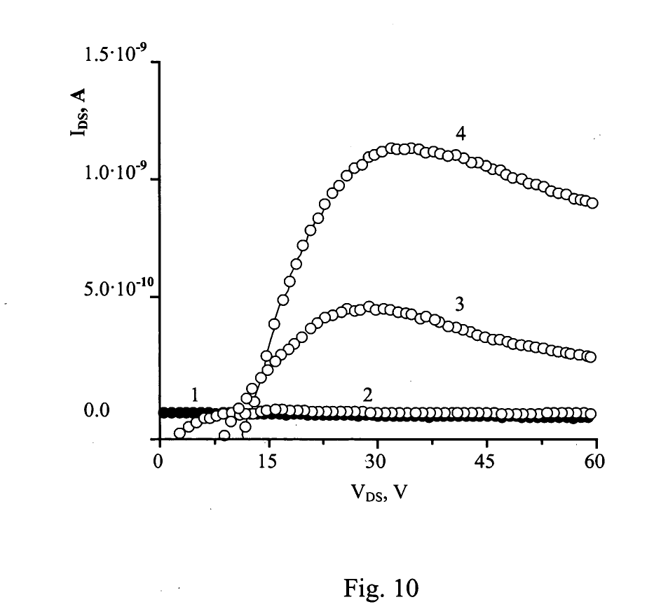

FIG. 10 illustrates the characteristics of other OFET sample, which one has the same characteristics of semiconductor structure as the first OFET sample reviewed above. The gate-source voltage (V_{GS}) had several values: VGS=0 (1); VGS=20, V (2); VGS=40, V (3); VGS=60, V (4). The aforementioned Figures demonstrate that a voltage between a source and a gate guides the current between a source and drain of the field-effect transistor. Thus, the experiments cited above have confirmed capacity of organic layers made by means of Cascade Crystallization Process and characterized by a globally ordered crystalline structure with intermolecular spacing of 3.4±0.3 Å in the direction of one crystal axis, formed by rodlike supramolecules comprising at least one polycyclic organic compound with conjugated π-system, and having electron-hole type of conductivity to serve as active layers in the organic thin-film transistors.

The preceding description is illustrative rather than limiting. Other embodiments and modifications may be readily apparent to those skilled in the art. All such embodiments and modifications should be considered part of the inventions and within the scope of the appended claims and any equivalents thereto.

1. An organic thin film transistor comprising
an organic semiconductor layer,
an insulator layer with at least a part of one surface in contact with at least a part of one surface of the semiconductor layer,
electrically conducting gate electrode located on the other surface of the insulator layer,
electrically conductive source and drain electrodes in contact with one surface of the organic semiconductor layer,
wherein said organic semiconductor layer is characterized by a globally ordered crystalline structure with intermolecular spacing of 3.4±0.3 Å in the direction of one crystal axis, is formed by rodlike supramolecules comprising at least one polycyclic organic compound with conjugated π-system, and possesses electron-hole type of conductivity.

2. The organic thin film transistor according to claim 1, further comprising a substrate which carries said organic semiconductor layer and insulator layer.

3. The organic thin film transistor according to claim 2, wherein said electrically conducting gate electrode is located on the substrate; the insulator layer is located on said electrically conducting gate electrode and is in contact with said gate electrode; the organic semiconductor layer is located on said insulator layer substantially overlapping with said gate electrode; and the electrically conductive source and drain electrodes are located on said organic semiconductor layer and are in contact with said layer.

4. The organic thin film transistor according to claim 2, wherein the electrically conductive source and drain electrodes are located on the substrate; the organic semiconductor layer is located on said source electrode, drain electrode and the substrate and is in contact with said source electrode, drain electrode and the substrate; the insulator layer is located on said organic semiconductor layer and is in contact with said layer; and said electrically conducting gate electrode is located on said insulator layer and is in contact with said insulator layer.

5. The organic thin film transistor according to claim 2, wherein said electrically conducting gate electrode is located on the substrate; the insulator layer is located on said electrically conducting gate electrode and is in contact with said gate electrode; the electrically conductive source and drain electrodes are located on said insulator layer and are in contact with said insulator layer; and the organic semiconductor layer is located on and in contact with said source electrode, drain electrode and the insulator layer.

6. The organic thin film transistor according to claim 2, wherein the organic semiconductor layer is located on the substrate; the electrically conductive source and drain electrodes are located on said organic semiconductor layer and are in contact with said organic semiconductor layer; the insulator layer is located on said source electrode, drain electrode and organic semiconductor layer and is in contact with said source and drain electrodes and said semiconductor layer; and the electrically conducting gate electrode is located on said insulator layer and is in contact with said insulator layer.

7. The organic thin film transistor according to claim 1, wherein electrically conductive source and drain electrodes are aligned with respect to said gate electrode.

8. The organic thin film transistor according to claim 1, further comprising an insulator passivation layer located on top of said transistor to protect the transistor from further processing exposures and from the ambient factors.

9. The organic thin film transistor according to claim 2, wherein the substrate is selected from the group comprising glass, plastic, quartz, and undoped silicon.

10. The organic thin film transistor according to claim 9, wherein said plastic substrate is selected from the group comprising polycarbonate, Mylar, and polyimide.

11. The organic thin film transistor according to claim 1, wherein the organic semiconductor layer is made of an organic semiconductor of n-type.

12. The organic thin film transistor according to claim 11, wherein the gate electrode is made of a material with a high electron work function.

13. The organic thin film transistor according to claim 12, wherein material of said gate electrode is selected from the group comprising nickel, gold, platinum, lead, ITO, and combinations thereof.

14. The organic thin film transistor according to claim 11, wherein the source and drain electrodes are made of a material with a low electron work function.

15. The organic thin film transistor according to claim 14, wherein material of said gate electrode is selected from the group comprising chromium, titanium, copper, aluminum, molybdenum, tungsten, indium, silver, calcium, and combinations thereof.

16. The organic thin film transistor according to claim 1, wherein the organic semiconductor layer is made of an organic semiconductor of p-type.

17. The organic thin film transistor according to claim 16, wherein the source and drain electrodes are made of a material with a low electron work function.

18. The organic thin film transistor according to claim 17, wherein material of said source and drain electrodes is selected from the group comprising chromium, titanium, copper, aluminum, molybdenum, tungsten, indium, silver, calcium, and combinations thereof.

19. The organic thin film transistor according to claim 18, wherein the gate electrode is made of a material with a high electron work function.

20. The organic thin film transistor according to claim 19, wherein material of said gate electrode is selected from the group comprising nickel, gold, platinum, lead, ITO, and combinations thereof.

21. The organic thin film transistor according to claim 1, wherein said gate electrode has a thickness in the range between 30 nm and 500 nm, and said electrode is produced by a process selected from the group comprising evaporation, sputtering, chemical vapor deposition, electrodeposition, spin coating, and electroless plating.

22. The organic thin film transistor according to claim 1, wherein material of said insulator layer is selected from the group comprising silicon dioxide, silicon oxide, barium strontium titanate, barium zirconate titanate, lead zirconate titanate, lead lanthanum titanate, barium titanate, strontium titanate, barium magnesium fluoride, tantalum pentoxide, titanium dioxide and yttrium trioxide.

23. The organic thin film transistor according to claim 1, wherein said insulator layer has a thickness in the range between 80 nm and 1000 nm.

24. The organic thin film transistor according to claim 1, wherein said insulator layer is produced by a process selected from the group comprising sputtering, chemical vapor deposition, sol gel coating, evaporation and laser ablation deposition.

25. The organic thin film transistor according to claim 1, wherein at least one electrically conducting gate electrode is a multilayer structure comprising layers made of different conducting materials.

26. The organic thin film transistor according to claim 1, wherein at least one electrically conducting source electrode is the multilayer structure comprising layers made of different conducting materials.

27. The organic thin film transistor according to claim 1, wherein at least one electrically conducting drain electrode is the multilayer structure comprising layers made of different conducting materials.
